(19) United States
(12) Patent Application Publication
(10) Pub. No.: US 2026/0090424 A1
(43) Pub. Date: Mar. 26, 2026

(54) SINGULATION INCORPORATING AN ETCHED METAL CHANNEL

(71) Applicant: Intel Corporation, Santa Clara, CA (US)

(72) Inventors: Jeremy D. ECTON, Gilbert, AZ (US); Bohan SHAN, Chandler, AZ (US); Brandon C. MARIN, Gilbert, AZ (US); Srinivas Venkata Ramanuja PIETAMBARAM, Chandler, AZ (US); Gang DUAN, Chandler, AZ (US)

(21) Appl. No.: 18/891,946

(22) Filed: Sep. 20, 2024

(51) Int. Cl. H01L 23/13; H01L 23/00; H01L 23/14; H01L 23/498; H01L 25/065; H05K 1/18

(52) U.S. Cl. CPC H10W 70/68; H05K 1/181; H10W 70/695; H10W 90/401; H10W 72/0198; H10W 72/252; H10W 74/10; H10W 90/00; H10W 90/724

(57) ABSTRACT

Embodiments disclosed herein may include an apparatus that includes a substrate with a first edge surface. In an embodiment, the substrate may comprise a glass layer. In an embodiment, a via is formed through a thickness of the substrate. In an embodiment, an organic dielectric layer is provided over the substrate, and the organic dielectric layer has a second edge surface. In an embodiment, a recess is formed into the second edge surface of the organic dielectric layer.

### BACKGROUND

Electronics packaging substrates may include a core. Existing core materials include organic dielectrics that comprise fiber reinforcement materials. As devices continue to scale in complexity, alternative core materials are desired. For example, package cores that include solid glass layers may be one potential option. Glass cores enables stiffer substrates, flatter surfaces, and improved dimensional stability.

However, glass substrates that are used for the core are more fragile than existing organic core materials. Singulation of glass core substrates into individual units can be particularly problematic. For example, conventional mechanical singulation processes may result in defect generation (e.g., cracks, seware defects, etc.) as well as dielectric delamination.

### BRIEF DESCRIPTION OF THE DRAWINGS

FIG. 1A is a cross-sectional illustration of a package substrate with a glass core and buildup layers that are singulated with an etching process that removes a sacrificial metal layer through a thickness of the package substrate, in accordance with an embodiment.

FIG. 1B is a cross-sectional illustration of a package substrate with a glass core and buildup layers that are singulated with an etching process that removes a sacrificial metal layer and produces a protrusion along an edge surface of the glass core, in accordance with an embodiment.

FIG. 1C is a cross-sectional illustration of a package substrate with a glass core embedded in a buffer layer and buildup layers that are singulated with an etching process that removes a sacrificial metal layer and produces recesses along edges of the buildup layers, in accordance with an embodiment.

FIG. 2A-2E are illustrations depicting a process for forming a package substrate with a sacrificial metal layer that is etched away during a singulation process, in accordance with an embodiment.

FIGS. 3A and 3B are cross-sectional illustrations depicting a singulation process that includes etching a sacrificial metal layer in order to produce a package substrate with a protrusion along an edge surface of a glass core, in accordance with an embodiment.

FIGS. 4A and 4B are cross-sectional illustrations depicting a singulation process that includes etching a sacrificial metal layer in order to produce a package substrate with recesses along an edge of the buildup layers over the glass core, in accordance with an embodiment.

FIGS. 5A and 5B are cross-sectional illustrations depicting a singulation process that includes etching through a sacrificial metal layer and a buffer layer around a glass core, in accordance with an embodiment.

FIG. 6 is a flow diagram of a process for singulating a package substrate using a sacrificial metal layer that is removed with a wet etching process, in accordance with an embodiment.

FIG. 7 is a cross-sectional illustration of an electronic system with a package substrate that includes a glass core that is singulated with a wet etching process, in accordance with an embodiment.

FIG. 8 is a schematic of a computing device built in accordance with an embodiment.

### EMBODIMENTS OF THE PRESENT DISCLOSURE

Described herein are package substrates that are singulated through the use of a sacrificial metal layer and an etching process, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, glass substrates used for package cores provides multiple advantages compared to organic dielectric substrates. For example, glass substrate cores may be stiffer, have flatter surfaces, and improved dimensional stability. However, the singulation process used in existing package substrate assembly flows may use a mechanical sawing process. Such mechanical sawing is not compatible with glass substrates since the sawing can lead to cracking, seware defects, dielectric delamination, and/or other damage to the glass substrate. As such, device yields are low.

Accordingly, embodiments disclosed herein may include a singulation process that does not rely on mechanical separation. Instead, embodiments may include an etching process, such as a wet etching process. The etch selectivity used to provide the etch-based singulation may be obtained through the fabrication of sacrificial metal layers within the glass substrate and/or in the buildup layers over and/or under the glass substrate. Due to the etch selectivity between the glass material and the metal and/or the etch selectivity between the organic dielectric material and the metal, the singulation process can be implemented with a wet etching process without the need for masking the package substrate. As such, the singulation process can be easily and cost-effectively implemented.

In some embodiments, the sacrificial metal layer passes entirely through a thickness of the glass core substrate. As such, the entirety of the glass core substrate can be singulated without a mechanical separation process. In other embodiments, a glass bridge may be provided across the sacrificial metal layer. Such an embodiment may provide improved mechanical stability of the panel until the final singulation is implemented. For example, the narrow bridge of glass may be cut with a singulation process, such as laser ablation or the like. However, since the bridge is relatively thin, there is not significant damage induced into the glass core substrate. In yet another embodiment, a buffer layer may be provided around individual units of the glass core substrate. The singulation process may then pass through the buffer layer instead of the glass core substrate. As such, minimal (if any) stress is applied to the glass core substrate in order to minimize or prevent damage to the glass core substrate.

In an embodiment, the overlying buildup layers may also have sacrificial metal layers in order to allow for the etch-based singulation through the package substrate. For example, the sacrificial metal layers in the buildup layers may be formed with the same plating and patterning processes used to form traces, vias, pads, or the like in the individual laminated layers. Due to inherent misalignment between layers, the edges of the buildup layers after singulation may include recesses and/or protrusions. Accordingly, the sidewall profile of the package substrate may have a non-planar profile, such as a stepped profile, in some embodiments.

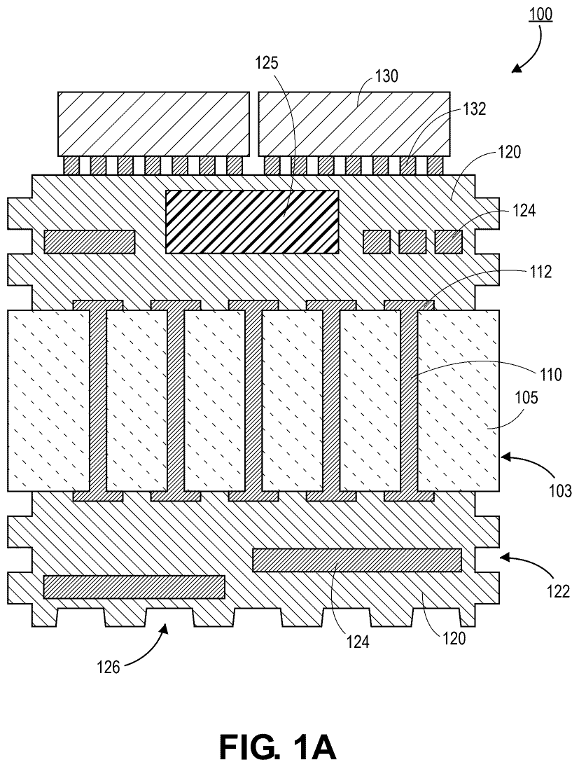

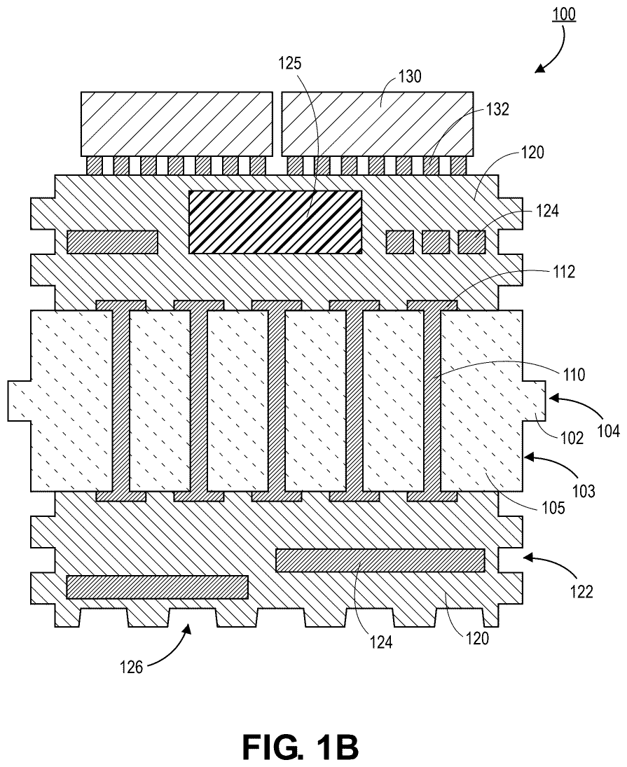

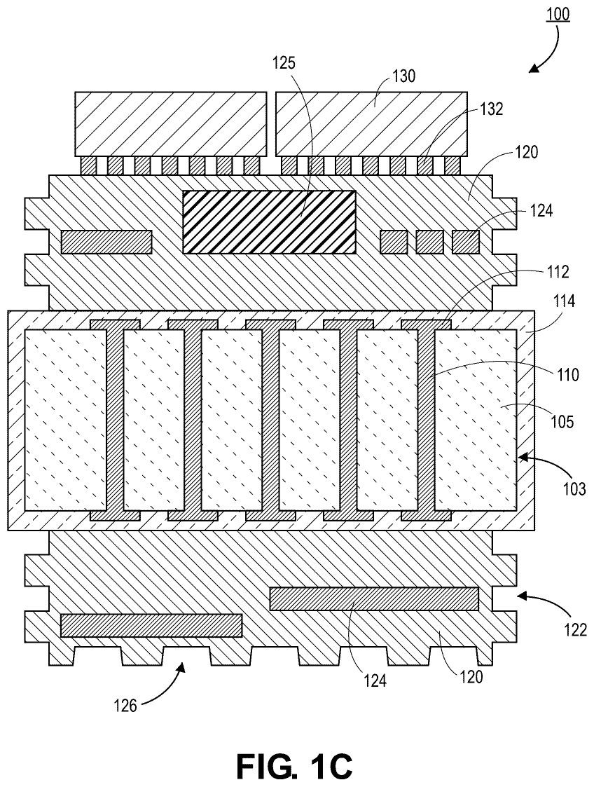

Referring now to FIG. 1A-1C, cross-sectional illustrations depicting portions of package substrates 100 are shown, in accordance with several different embodiments. In FIG. 1A, the glass core substrate 105 has a substantially planar edge surface 103 with buildup layers 120 that include one or more recesses 122. In FIG. 1B, the glass core substrate 105 comprises a protrusion 102, and the buildup layers 120 may include one or more recesses 122. In FIG. 1C, the glass core substrate 105 is embedded in a buffer layer 114, and the buildup layers 120 comprise one or more recesses 122.

Referring now to FIG. 1A, a cross-sectional illustration of a portion of a package substrate 100 is shown, in accordance with an embodiment. In an embodiment, the package substrate 100 may comprise a glass core substrate 105 with buildup layers 120 above and/or below the glass core substrate 105. The buildup layers 120 may comprise a plurality of laminated organic dielectric layers, such as organic buildup film.

In an embodiment, the glass core substrate 105 may be substantially all glass. The glass core substrate 105 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, the glass core substrate 105 may be distinguished from, for example, the “prepreg” or “FR4” core of a Printed Circuit Board (PCB) substrate which typically comprises glass fibers embedded in a resinous organic material, such as an epoxy.

The glass core substrate 105 may have any suitable dimensions. In a particular embodiment, the glass core substrate 105 may have a thickness that is approximately 50 μm or greater. For example, the thickness of the glass core substrate 105 may be between approximately 50 μm and approximately 1.4 mm. Though, smaller or larger thicknesses may also be used. The glass core substrate 105 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the glass core substrate 105 (from an overhead plan view) may be between approximately 10 mm×10 mm and approximately 250 mm×250 mm. In an embodiment, the glass core substrate 105 may have a first side that is perpendicular or orthogonal to a second side. In a more general embodiment, the glass core substrate 105 may comprise a rectangular prism volume with sections (e.g., vias) removed and filled with other materials (e.g., metal, etc.).

The glass core substrate 105 may comprise a single monolithic layer of glass. In other embodiments, the glass core substrate 105 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass core substrate 105 may each have a thickness less than approximately 50 μm. For example, discrete layers of glass in the glass core substrate 105 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The glass core substrate 105 may be any suitable glass formulation that has the necessary mechanical robustness and compatibility with semiconductor packaging manufacturing and assembly processes. For example, the glass core substrate 105 may comprise aluminosilicate glass, borosilicate glass, alumino-borosilicate glass, silica, fused silica, or the like. In some embodiments, the glass core substrate 105 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the glass core substrate 105 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass core substrate 105 may comprise at least 23 percent silicon (by weight) and at least 26 percent oxygen (by weight). In some embodiments, the glass core substrate 105 may further comprise at least 5 percent aluminum (by weight).

In an embodiment, the glass core substrate 105 may comprise one or more electrically conductive vias 110 that pass through a thickness of the glass core substrate 105. In the illustrated embodiment, the vias 110 have substantially vertical sidewalls.

Though, in other embodiments, the sidewalls of the vias 110 may be sloped. For example, the vias 110 may have a tapered cross-sectional shape, or the vias 110 may have an hourglass shaped cross-section. Pads 112 may be provided over and/or under the vias 110. In an embodiment, the vias 110 and the pads 112 may comprise copper or any other suitable electrically conductive material.

In an embodiment, the glass core substrate 105 may have an edge surface 103. In an embodiment, the edge surface 103 may be substantially linear. The illustrated edge surface 103 is substantially vertical (i.e., orthogonal to a top or bottom surface of the glass core substrate 105). Though, other embodiments may include an edge surface 103 that is sloped or otherwise non-vertical. The non-vertical slope of the edge surface 103 may be dictated by a process used to form a sacrificial metal layer (not shown in FIG. 1A) that is used during the singulation process.

In an embodiment, the package substrate 100 may further comprise buildup layers 120 over and/or under the glass core substrate 105. The buildup layers 120 may comprise individual organic dielectric layers that are laminated over each other. The buildup layers 120 may comprise electrically conductive routing, such as the pads 112, traces 124, vias, and/or the like. In an embodiment, an edge of the buildup layers 120 may comprise one or more recesses 122. The recesses 122 may be the result of misalignment in a sacrificial metal layer (not shown in FIG. 1A) that is used during the singulation process.

In the illustrated embodiment, all of the recesses 122 have a similar depth. Though, embodiments may include recesses with different depths. For example, the depth of the recesses 122 may be up to approximately 1.0 μm, up to approximately 5.0 μm, up to approximately 10 μm, or up to approximately 25 μm. In an embodiment, the recesses 122 may be aligned with traces 124. That is, the top and bottom of the recess 122 may be substantially coplanar with a top and bottom of a trace 124, respectively.

In an embodiment, a bridge 125 may be coupled to one of the buildup layers 120. For example, a bridge 125 is embedded in the buildup layer 120 above the glass core substrate 105 in FIG. 1A. The bridge 125 may comprise a silicon substrate, a glass substrate, or any other dimensionally stable substrate. Electrically conductive routing (not shown) may be provided on and/or within the bridge 125 in order to electrically couple dies 130 together. For example, an electrical path from a first die 130 may pass through an interconnect 132, pass into the buildup layer 120 and into the bridge 125. The electrical path may then continue from the bridge 125 through the buildup layer 120, and into the interconnect 132 coupled to a second die 130.

In an embodiment, the dies 130 may include any suitable die, such as a processor (e.g., a central processing unit (CPU), a graphics processing unit (GPU), an XPU, etc.), a memory die, a communications die, and/or the like. The interconnects 132 may be any suitable first level interconnect (FLI) architecture, such as a solder ball, a copper bump, a hybrid bonding interface, or the like. In an embodiment, the buildup layer 120 under the glass core substrate 105 may have openings 126 for receiving second level interconnects (SLIs) used to couple the package substrate 100 to a board (not shown in FIG. 1A).

Referring now to FIG. 1B, a cross-sectional illustration of a portion of a package substrate 100 is shown, in accordance with an additional embodiment. In an embodiment, the package substrate 100 in FIG. 1B may be similar to the package substrate 100 in FIG. 1A, with the exception of the edge surface 103 of the glass core substrate 105. Instead of having a planar edge surface 103, a protrusion 102 may extend out from the planar edge surface 103. The protrusion 102 may be a residual structure from the singulation process. In such an embodiment, the sacrificial metal layer (not shown in FIG. 1B) may not pass entirely through a thickness of the glass core substrate 105. For example, a glass bridge may pass across a width of the sacrificial metal layer.

During the singulation process, the sacrificial metal layer is etched, and the glass bridge may remain between individual units of the glass core substrates within a panel. The glass bridge may then be singulated with an additional singulation process (e.g., laser ablation) in order to fully singulate individual package substrates. While a laser ablation process or the like may be used, the small thickness of the glass bridge (e.g., 50 μm or less, 25 μm or less, or 10 μm or less) requires minimal laser ablation. As such, substantial stress and damage is not introduced into the glass core substrate 105.

Further, the combination of an etching process and a laser ablation process may result in distinctive surface roughnesses along the edge surface 103 and an edge 104 of the protrusion 102. For example, a surface roughness of the edge surface 103 may be lower than a surface roughness of the edge 104 of the protrusion 102 due to the different processing operations used to expose the edge surface 103 and the edge 104 of the protrusion 102.

Referring now to FIG. 1C, a cross-sectional illustration of a portion of a package substrate 100 is shown, in accordance with an embodiment. In an embodiment, the package substrate 100 may be similar to the package substrate 100 in FIG. 1A, with the exception of the glass core substrate 105. Particularly, a buffer layer 114 may be provided along the edge surface 103 of the glass core substrate 105. In some embodiments, the buffer layer 114 may be provided around an entire perimeter of the glass core substrate 105 and over the top and/or bottom surfaces of the glass core substrate 105. The buffer layer 114 may comprise a dielectric material, such as an organic dielectric material. In some embodiments, the buffer layer 114 may comprise a polymer, an oxide, a nitride, or the like.

The buffer layer 114 may be provided between individual glass core substrate 105 units within a panel. As such, singulation of the buffer layer 114 may include laser ablation or sawing instead of the glass core substrate 105. This prevents or mitigates stress transfer into the glass core substrate 105 and prevents damage to the glass core substrate 105. Additionally, the residual portions of the buffer layer 114 over the edge surface 103 protect the glass core substrate 105 from damage during downstream processing (e.g., due to contact with other objects during assembly or the like). Accordingly, the buffer layer 114 may be used to further enhance the robustness of the package substrate 100.

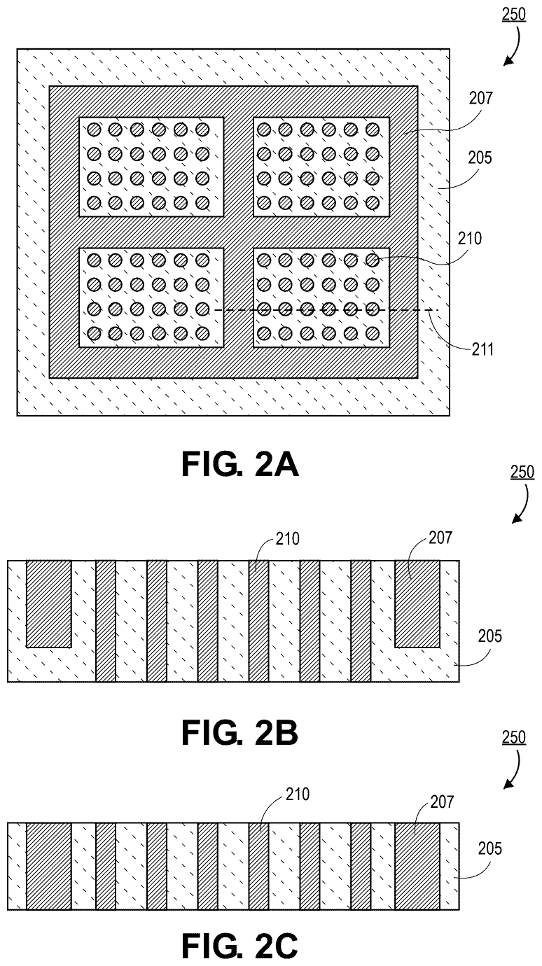

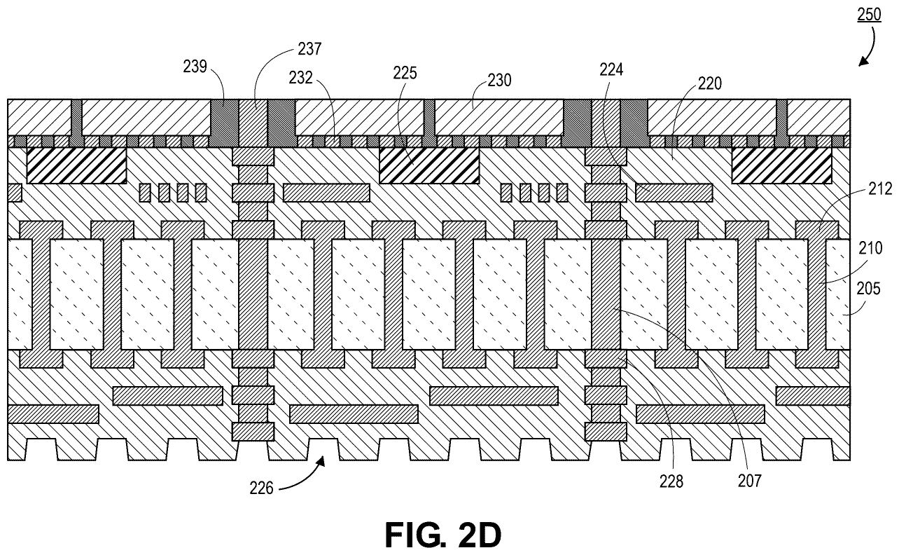

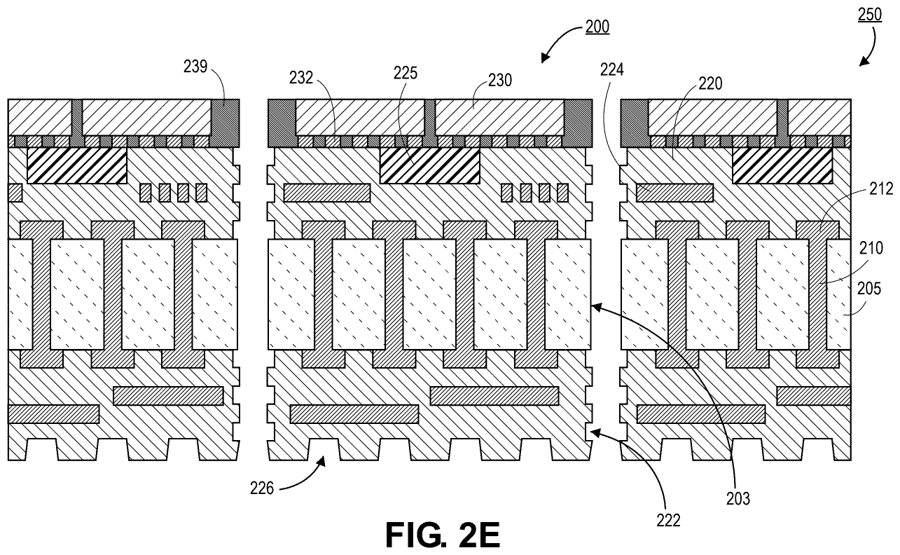

Referring now to FIG. 2A-2E, a series of illustrations depicting a process for forming a package substrate 200 with a glass core substrate 205 that is singulated with an etching process is shown, in accordance with an embodiment.

Referring now to FIG. 2A, a plan view illustration of a panel 250 is shown, in accordance with an embodiment. In an embodiment, the panel 250 may comprise a glass core substrate 205. The glass core substrate 205 may be similar to any of the glass core substrates described in greater detail herein. In an embodiment, a plurality of vias 210 may be formed through a thickness of the glass core substrate 205. The vias 210 may comprise an electrically conductive material, such as copper. Additionally, a sacrificial metal layer 207 may be provided around regions of the glass core substrate 205. For example, four regions of the glass core substrate 205 are surrounded by the sacrificial metal layer 207, such as a copper layer.

Referring now to FIG. 2B, a cross-sectional illustration of the panel 250 along line 211 in FIG. 2A is shown, in accordance with an embodiment. As shown, the vias 210 pass through an entire thickness of the glass core substrate 205, and the sacrificial metal layer 207 extends partially through a thickness of the glass core substrate 205. A sacrificial metal layer 207 that partially passes through the thickness of the glass core substrate 205 leaves the glass core substrate 205 as a continuous substrate when trenches for the sacrificial metal layer 207 are formed.

In FIG. 2B, both the vias 210 and the sacrificial metal layer 207 have substantially vertical sidewalls. Though, in other embodiments the sidewalls of one or both of the vias 210 and the sacrificial metal layer 207 may be sloped. For example, the vias 210 may have an hourglass shaped cross-section. The cross-sectional shape of the vias 210 and the sacrificial metal layer 207 may be dictated by the process used to form the vias 210 and the sacrificial metal layer 207. For example, sloped sidewalls may be present when a laser assisted etching process is used to form the openings for the vias 210 and/or the sacrificial metal layer 207.

Referring now to FIG. 2C, a cross-sectional illustration of the panel 250 after the glass core substrate 205 is recessed to expose a bottom surface of the sacrificial metal layer 207 is shown, in accordance with an embodiment. In some embodiments, the recessing process may use a chemical mechanical polishing (CMP) process or the like. When the polishing process exposes the bottom of the sacrificial metal layer 207, the glass core substrate 205 may be secured to a carrier (not shown). Though, it is to be appreciated that the sacrificial metal layer 207 may provide sufficient mechanical coupling to the glass core substrate 205 to retain the panel 250 as a single component without portions of the glass core substrate 205 detaching from each other.

Referring now to FIG. 2D, a cross-sectional illustration of the panel 250 after buildup layers 220 and additional components are added is shown, in accordance with an embodiment. In an embodiment, the buildup layers 220 may comprise a plurality of laminated organic dielectric layers, such as organic buildup film. In an embodiment, electrically conductive routing, such as traces 224, pads 212, vias, and/or the like may be embedded within the buildup layers 220.

Additionally, sacrificial frames 228 may be provided through a thickness of the buildup layers 220. As shown, the sacrificial frames 228 may comprise a plurality of stacked metal layers (e.g., copper layers). Each layer of the sacrificial frames 228 may be formed in parallel with the traces 224 formed in that layer. As such, the thickness of each layer of the sacrificial frames 228 may be substantially equal to a thickness of the traces 224 in the same layer. In an embodiment, the sacrificial frames 228 may have sidewalls with a stepped profile. The stepped profile may be the result of misalignment between the individual layers within the sacrificial frames 228. The offset between the edges of each layer may be up to approximately 25 μm, up to approximately 10 μm, or up to approximately 5 μm. Though, larger offsets may also be present in some embodiments.

In an embodiment, a bridge 225 may also be embedded in (or provided on) the upper buildup layer 220. The bridge 225 may electrically couple a pair of dies 230 together. The dies 230 may be coupled to the buildup layer 220 and/or the bridge 225 through interconnects 232, such as any suitable FLI architecture. In an embodiment, a mold layer 239 may be provided over the dies 230. A sacrificial metallic frame 237 may be formed through the mold layer 239 over the sacrificial frame 228. In an embodiment, openings 226 may be provided along the bottom buildup layer 220 in order to accommodate SLIs for coupling the bottom buildup layer 220 to a board (not shown in FIG. 2D).

As can be appreciated, a continuous metal path is provided from a top surface of the panel 250 to a bottom surface of the panel 250. For example, the continuous metal path may comprise the sacrificial metallic frame 237 and the sacrificial frames 228 on opposite sides of the sacrificial metal layer 207 through the glass core substrate 205. As such, removal of the continuous metal path allows for singulation of the panel 250 into individual units.

Referring now to FIG. 2E, a cross-sectional illustration of the panel 250 after singulation is shown, in accordance with an embodiment. As shown, the panel 250 is singulated into individual package substrates 200. The singulation process may include etching away the continuous metal path through the thickness of the panel 250. For example, an etching chemistry (e.g., a wet etching chemistry) may be used to selectively remove the metal of the continuous metal path without significantly etching the mold layer 239, the buildup layers 220, or the glass core substrate 205.

As shown, the glass core substrate 205 may have a substantially linear edge surface 203, and the buildup layers 220 may have an edge surface with one or more recesses 222. The recesses 222 may be the result of misalignment in the individual layers of the sacrificial frames 228. Since the individual layers of the sacrificial frames 228 were aligned with the traces 224, the recesses 222 may also be aligned with the traces 224. That is, a top surface of the recess 222 and a bottom surface of the recess 222 may be substantially coplanar with the top surface of the trace 224 in the same layer and the bottom surface of the trace 224 in the same layer, respectively.

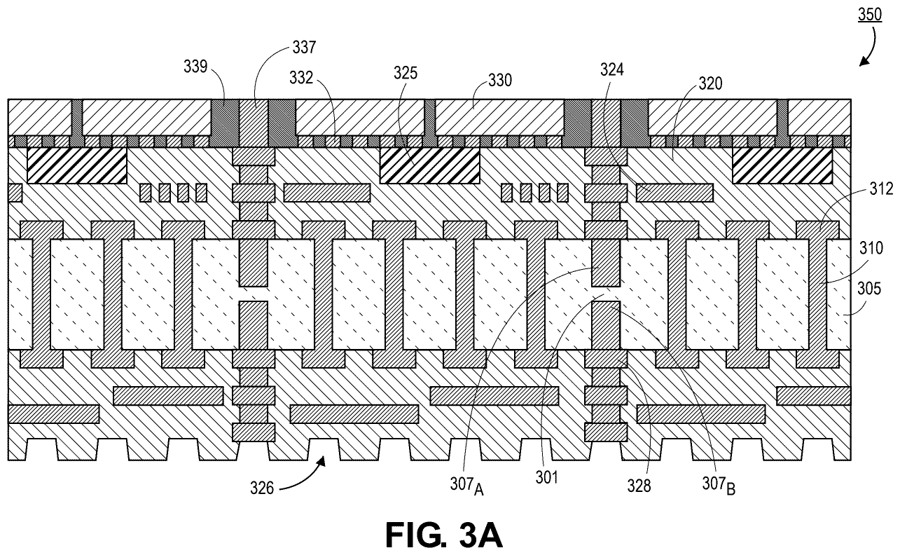

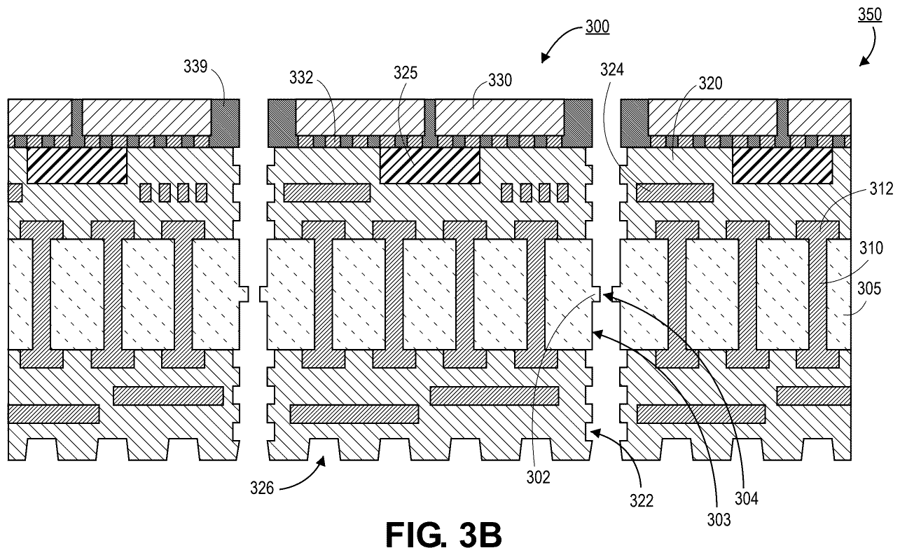

Referring now to FIGS. 3A and 3B, a pair of cross-sectional illustrations depicting a singulation process in accordance with another embodiment is shown, in accordance with an embodiment.

Referring now to FIG. 3A, a cross-sectional illustration of a panel 350 with a glass core substrate 305 is shown, in accordance with an embodiment. In an embodiment, the panel 350 shown in FIG. 3A may be similar to the panel 250 in FIG. 2A, with the exception of the structure of the sacrificial metal layers 307. For example, the panel 350 may comprise a glass core substrate 305 that comprises vias 310 with overlying and underlying pads 312. Traces 324 and the like may be embedded in buildup layers 320. In some embodiments, dies 330 that are coupled to the buildup layer 320 by interconnects 332 may be embedded in a mold layer 339 and electrically coupled together by a bridge 325. Openings 326 may be provided in the buildup layer 320 below the glass core substrate 305 to accommodate SLIs. In an embodiment, sacrificial frames 328 with stepped sidewalls may pass through thicknesses of the buildup layers 320 and sacrificial metallic frames 337 may pass through the mold layer 339.

In an embodiment, a glass bridge 301 may cross a width of the sacrificial metal layers 307 to form an upper sacrificial metal layer 307_{A} and a lower sacrificial metal layer 307_{B}. The glass bridge 301 may be useful for maintaining the structural integrity of the panel 350 during fabrication. In some embodiments, the glass bridge 301 is positioned at an approximate midpoint between a top surface of the glass core substrate 305 and a bottom surface of the glass core substrate 305. Though, the glass bridge 301 may be positioned at any location between the top surface of the glass core substrate 305 and the bottom surface of the glass core substrate 305. The glass bridge 301 may also be provided along the top surface of the glass core substrate 305 or the bottom surface of the glass core substrate 305. In such an embodiment, the glass bridge 301 may not separate two regions of the sacrificial metal layer 307. Instead, the glass bridge 301 may be above or below the sacrificial metal layer 307.

Referring now to FIG. 3B, a cross-sectional illustration of the panel 350 after singulation to form individual package substrates 300 is shown, in accordance with an embodiment. In an embodiment, the singulation process may include a wet etching process that selectively removes the metal path. For example, an etching chemistry (e.g., a wet etching chemistry, such as a chemistry comprising cupric chloride or an ammoniacal alkaline etchant) may be used to selectively remove the metal of the metal path (e.g., the sacrificial metallic frames 337, the sacrificial frames 328, and the sacrificial metal layers 307_{A} and 307_{B} without significantly etching the mold layer 339, the buildup layers 320, or the glass core substrate 305. This may result in the formation of recesses 322 in the sidewalls of the buildup layers 320, similar to other embodiments described herein.

However, as can be appreciated, the glass bridge 301 may still remain after the etching process. As such, an additional singulation process (e.g., laser ablation, sawing, etc.) may be used to sever the glass bridge 301. In an embodiment, the severed glass bridge 301 may result in the formation of protrusions 302 along the edge surface 303 of the glass core substrates 305. Since different processing operations were used to form the edge surface 303 and the outer surface 304 of the protrusion 302, the surface roughnesses of the edge surface 303 and the outer surface 304 of the protrusion 302 may be different. For example, the outer surface 304 of the protrusion 302 may have a higher surface roughness than the edge surface 303 in some embodiments.

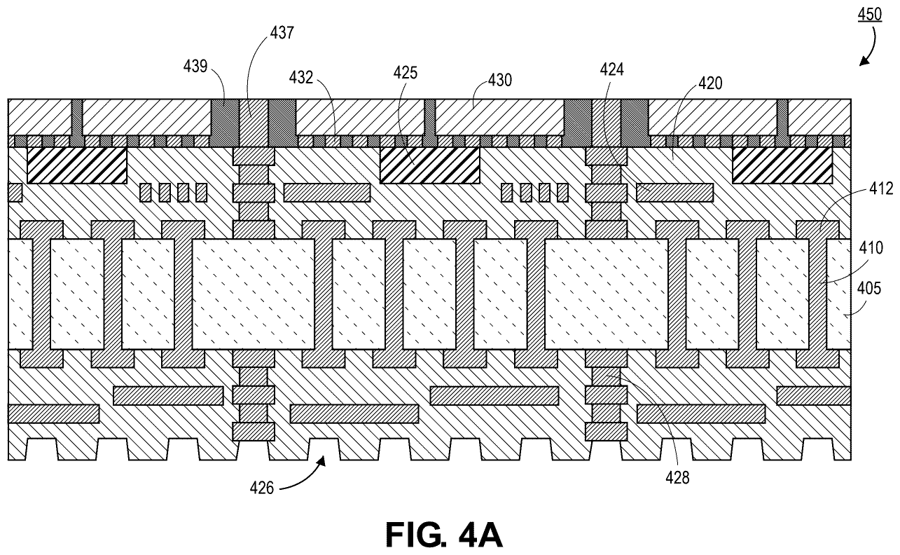

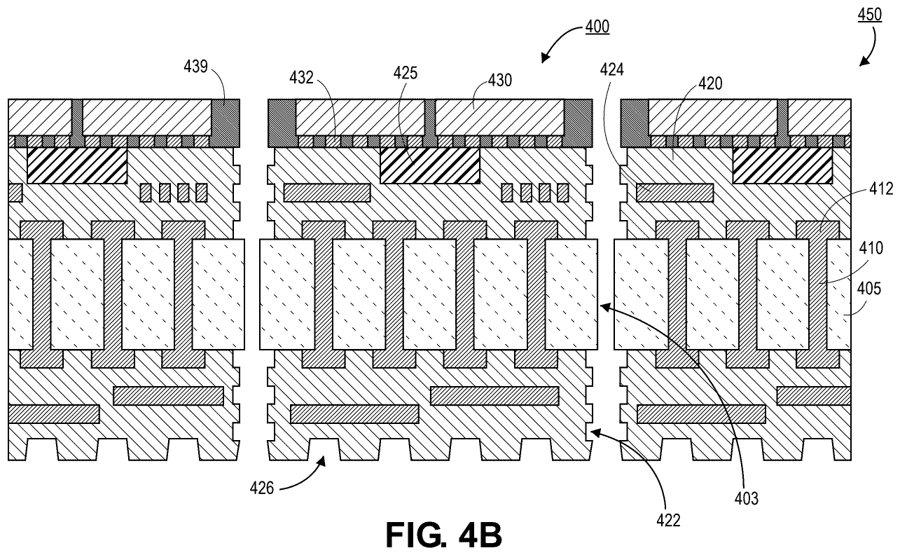

Referring now to FIGS. 4A and 4B, a pair of cross-sectional illustrations depicting a singulation process in accordance with another embodiment is shown, in accordance with an embodiment.

Referring now to FIG. 4A, a cross-sectional illustration of a panel 450 with a glass core substrate 405 is shown, in accordance with an embodiment. In an embodiment, the panel 450 shown in FIG. 4A may be similar to the panel 250 in FIG. 2A, with the exception of the lack of sacrificial metal layers. For example, the panel 450 may comprise a glass core substrate 405 that comprises vias 410 with overlying and underlying pads 412. Traces 424 and the like may be embedded in buildup layers 420. In some embodiments, dies 430 that are coupled to the buildup layer 420 by interconnects 432 may be embedded in a mold layer 439 and electrically coupled together by a bridge 425. Openings 426 may be provided in the buildup layer 420 below the glass core substrate 405 to accommodate SLIs. In an embodiment, sacrificial frames 428 with stepped sidewalls may pass through thicknesses of the buildup layers 420 and sacrificial metallic frames 437 may pass through the mold layer 439. Since there are no sacrificial metal layers through the glass core substrate 405, the ultimate singulation of the glass core substrate 405 may be implemented with a laser ablation process or the like.

Referring now to FIG. 4B, a cross-sectional illustration of the panel 450 after singulation to form individual package substrates 400 is shown, in accordance with an embodiment. In an embodiment, the singulation process may include a wet etching process that selectively removes the metal path. For example, an etching chemistry (e.g., a wet etching chemistry) may be used to selectively remove the metal of the metal path (e.g., the sacrificial metallic frames 437 and the sacrificial frames 428, without significantly etching the mold layer 439, the buildup layers 420, or the glass core substrate 405. This may result in the formation of recesses 422 in the sidewalls of the buildup layers 420, similar to other embodiments described herein.

However, substantially the entire thickness of the glass core substrate 405 may remain after the etching process. As such, an additional singulation process (e.g., laser ablation, etc.) may be used to singulate the glass core substrate 405. In an embodiment, the continuous laser ablation of the glass core substrate 405 may result in the formation of edge surfaces 403 that are substantially planar (e.g., vertical or sloped). The surface roughness of the edge surfaces 403 may be relatively high due to the laser ablation process. For example, a surface roughness of the edge surfaces 403 may be higher than a surface roughness of a top surface or a bottom surface of the glass core substrate 405.

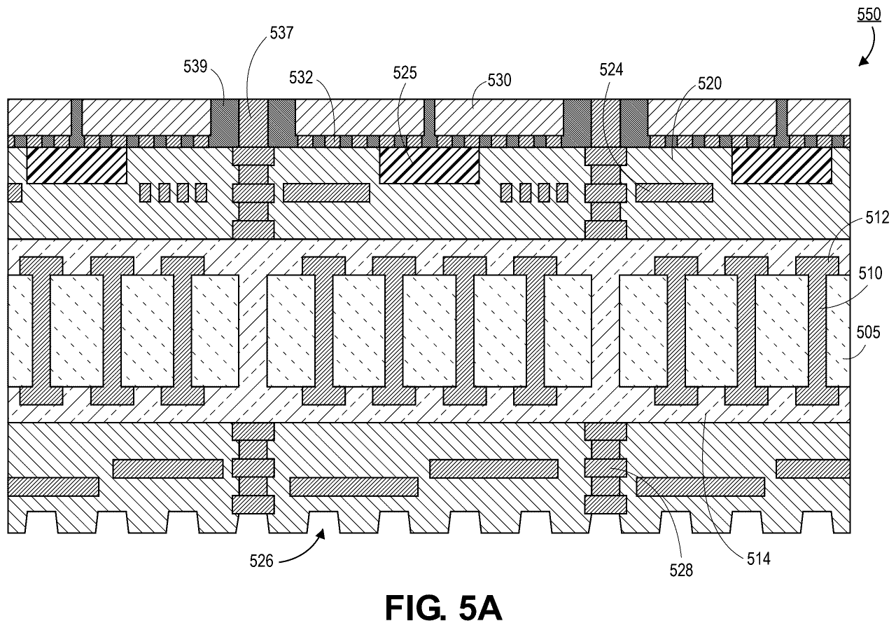

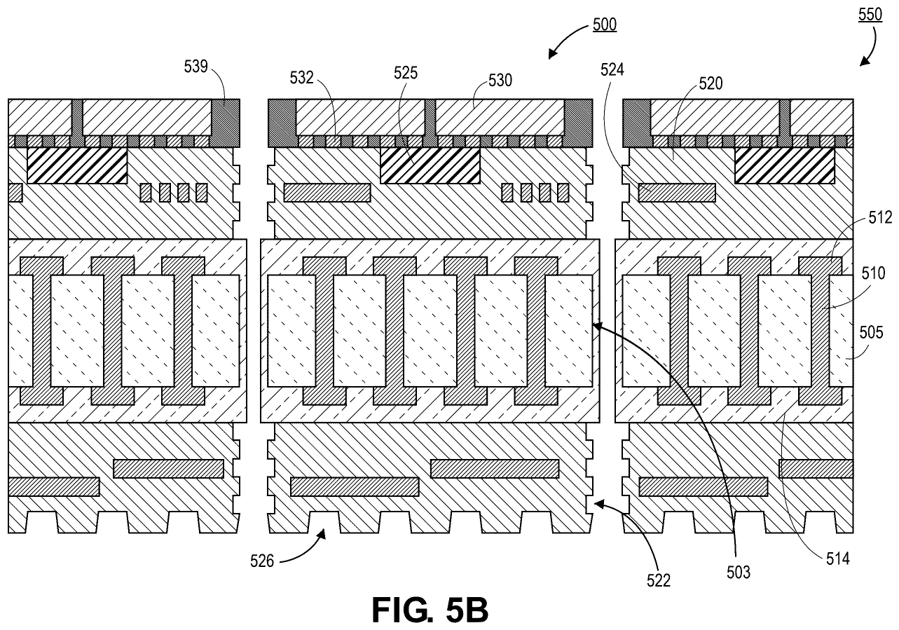

Referring now to FIGS. 5A and 5B, a pair of cross-sectional illustrations depicting a singulation process in accordance with another embodiment is shown, in accordance with an embodiment.

Referring now to FIG. 5A, a cross-sectional illustration of a panel 550 with a glass core substrate 505 is shown, in accordance with an embodiment. In an embodiment, the panel 550 shown in FIG. 5A may be similar to the panel 250 in FIG. 2A, with the exception of the addition of a buffer layer 514 around units of the glass core substrate 505. For example, the panel 550 may comprise a glass core substrate 505 that comprises vias 510 with overlying and underlying pads 512. Traces 524 and the like may be embedded in buildup layers 520. In some embodiments, dies 530 that are coupled to the buildup layer 520 by interconnects 532 may be embedded in a mold layer 539 and electrically coupled together by a bridge 525. Openings 526 may be provided in the buildup layer 520 below the glass core substrate 505 to accommodate SLIs. In an embodiment, sacrificial frames 528 with stepped sidewalls may pass through thicknesses of the buildup layers 520 and sacrificial metallic frames 537 may pass through the mold layer 539.

In an embodiment, gaps between the units of the glass core substrate 505 may be filled by the buffer layer 514. For example, the buffer layer 514 may comprise a dielectric material, such as an oxide, a nitride, a polymer, or the like. The portion of the buffer layer 514 between the units of the glass core substrate 505 may be aligned under the sacrificial frames 528. The buffer layer 514 provides a medium to cut through in order to prevent the transfer of stress into the glass core substrate 505 during singulation. In an embodiment, the buffer layer 514 may be also be provided over a top surface and a bottom surface of the glass core substrate 505.

Referring now to FIG. 5B, a cross-sectional illustration of the panel 550 after singulation to form individual package substrates 500 is shown, in accordance with an embodiment. In an embodiment, the singulation process may include a wet etching process that selectively removes the metal of the metal path through a thickness of the panel 550. For example, an etching chemistry (e.g., a wet etching chemistry) may be used to selectively remove the metal of the metal path (e.g., the sacrificial metallic frames 537 and the sacrificial frames 528), without significantly etching the mold layer 539, the buildup layers 520, or the glass core substrate 505. This may result in the formation of recesses 522 in the sidewalls of the buildup layers 520, similar to other embodiments described herein.

However, the buffer layer 514 prevents complete singulation of the panel 550. In some embodiments, an additional singulation process (e.g., laser ablation, etc.) can be used to cut through the portions of the buffer layer 514 between each of the package substrates 500. As such, a portion of the buffer layer 514 may remain along the edge surfaces 503 of the glass core substrate 505. Keeping a portion of the buffer layer 514 along the edge surfaces 503 may provided additional protection to the glass core substrate 505 during downstream processing, installation, and/or the like.

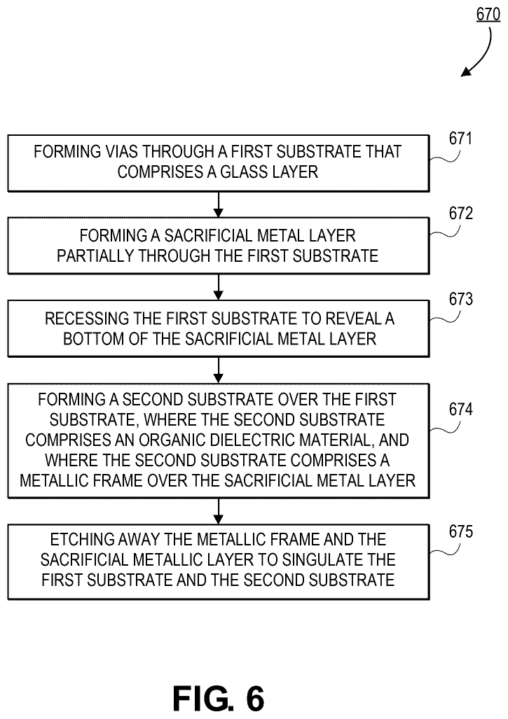

Referring now to FIG. 6, a flow diagram of a process 670 for singulating a panel with a glass substrate is shown, in accordance with an embodiment. In an embodiment, the process 670 may begin with operation 671, which comprises forming vias through a first substrate that comprises a glass layer. In an embodiment, the first substrate may be similar to any of the glass core substrates described in greater detail herein. The first substrate may have a panel form factor or any other form factor for fabricating a plurality of package substrates.

In an embodiment, the process 670 may continue with operation 672, which comprises forming a sacrificial metal layer partially through the first substrate. In an embodiment, the sacrificial metal layer may comprise copper or the like. The process 670 may then continue with operation 673, which comprises recessing the first substrate to reveal a bottom of the sacrificial metal layer. The recessing process may include a CMP process or the like. In some embodiments, the sacrificial metal layer may have a gap. That is, a glass bridge may cross through a width of a portion of the sacrificial metal layer in some embodiments.

In an embodiment, the process 670 may continue with operation 674, which comprises forming a second substrate over the first substrate. In an embodiment, the second substrate comprises an organic dielectric material, and a metallic frame is provided over the sacrificial metal layer. The metallic frame may include a stepped sidewall surface due to misalignment between multiple metal layers that are stacked to form the metallic frame.

In an embodiment, the process 670 may continue with operation 675, which comprises etching away the metallic frame and the sacrificial metallic layer to singulate the first substrate and the second substrate. In embodiments where the sacrificial metal layer has a gap, a laser ablation process may be used to sever the glass bridge that spans across a width of the sacrificial metal layer.

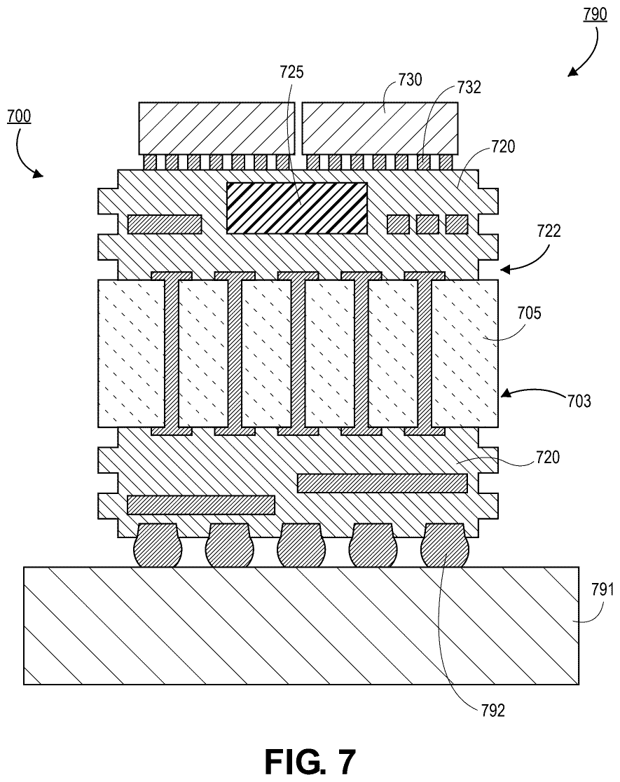

Referring now to FIG. 7, a cross-sectional illustration of an electronic system 790 is shown, in accordance with an embodiment. In an embodiment, the electronic system 790 may comprise a board 791, such as a printed circuit board (PCB), a motherboard, or the like. In an embodiment, the board 791 may be electrically coupled to a package substrate 700 by interconnects 792. The interconnects 792 may comprise solder balls, sockets, pins, or any other suitable SLI architecture.

In an embodiment, the package substrate 700 may be similar to any of the package substrates described in greater detail herein. For example, the package substrate 700 may comprise a glass core substrate 705 between buildup layers 720. The glass core substrate 705 may have an edge surface 703 that is substantially linear. Though, other embodiments may include a protrusion extending out from the edge surface 703. The buildup layers 720 may comprise one or more recesses 722 in some embodiments.

In an embodiment, one or more dies 730 may be electrically coupled to the package substrate 700 through interconnects 732. In an embodiment, the interconnects 732 may comprise solder balls, copper bumps, hybrid bonding interfaces, or any other suitable FLI architecture. In an embodiment, the one or more dies 730 may comprise any type of die, such as processor (e.g., a central processing unit (CPU), a graphics processing unit (GPU), an XPU, etc.), a memory die, a communications die, and/or the like. In some embodiments, a bridge 725 that is embedded in the buildup layer 720 or provided over the buildup layer 720 may electrically couple two dies 730 together. That is, an electrically conductive path may be provided from a first die 730 to a second die 730, and the electrically conductive path may pass through and/or over the bridge 725.

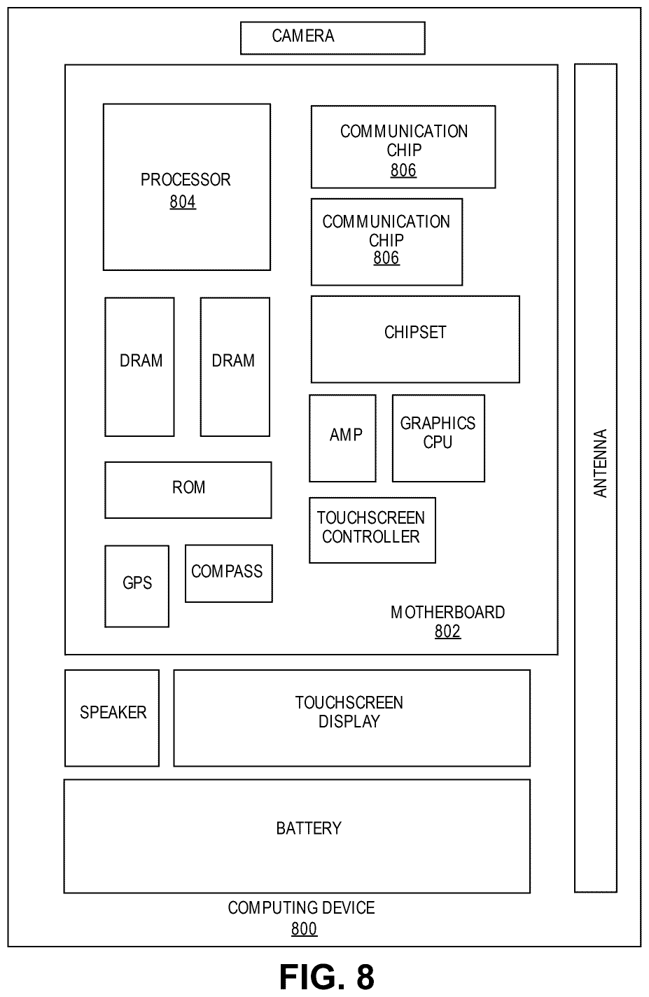

FIG. 8 illustrates a computing device 800 in accordance with one implementation of the disclosure. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the disclosure, the integrated circuit die of the processor may be part of an electronic package that comprises a package substrate that is singulated through the use of a sacrificial metal layer and an etching process, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the disclosure, the integrated circuit die of the communication chip may be part of an electronic package that comprises a package substrate that is singulated through the use of a sacrificial metal layer and an etching process, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims.

Rather, the scope of the disclosure is to be determined entirely by the following claims, which are to be construed in accordance with established doctrines of claim interpretation.

Example 1: an apparatus, comprising: a substrate with a first edge surface, wherein the substrate comprises a glass layer; a via through a thickness of the substrate; an organic dielectric layer over the substrate with a second edge surface; and a recess into the second edge surface.

Example 2: the apparatus of Example 1, further comprising: a plurality of recesses into the second edge surface.

Example 3: the apparatus of Example 2, wherein at least two of the plurality of recesses have depths from the second edge surface that are different from each other.

Example 4: the apparatus of Examples 1-3, wherein a protrusion extends out from the first edge surface.

Example 5: the apparatus of Example 4, wherein the protrusion is at an approximate midpoint between a top surface of the substrate and a bottom surface of the substrate.

Example 6: the apparatus of Example 4 or Example 5, wherein the first edge surface has a first surface roughness and a third edge surface of the protrusion has a second surface roughness that is greater than the first surface roughness.

Example 7: the apparatus of Examples 1-6, further comprising: a bridge embedded within the organic dielectric layer, wherein the bridge electrically couples a first die over the organic dielectric layer to a second die over the organic dielectric layer.

Example 8: the apparatus of Examples 1-7, further comprising: a dielectric layer over the first edge surface of the substrate.

Example 9: the apparatus of Example 8, wherein the dielectric layer is over a top surface and a bottom surface of the substrate.

Example 10: the apparatus of Examples 1-9, wherein the substrate is electrically coupled to a board.

Example 11: an apparatus, comprising: a glass core, wherein the glass core has a protrusion extending out from a first edge surface of the glass core; and an organic dielectric layer over the glass core, wherein the organic dielectric layer comprises a first recess and a second recess into a second edge surface of the organic dielectric layer.

Example 12: the apparatus of Example 11, wherein the first recess has a first depth and the second recess has a second depth that is different than the first depth.

Example 13: the apparatus of Example 12, wherein the first depth is up to approximately 25 μm.

Example 14: the apparatus of Examples 11-13, wherein the first edge surface has a first roughness and the protrusion has a third edge surface with a second roughness, and wherein the second roughness is greater than the first roughness.

Example 15: the apparatus of Examples 11-14, wherein the first edge surface is offset from the second edge surface.

Example 16: the apparatus of Examples 11-15, further comprising: an electrically conductive via through the glass core.

Example 17: the apparatus of Examples 11-16, further comprising: a bridge coupled to the organic dielectric layer, wherein the bridge electrically couples a first die over the organic dielectric layer to a second die over the organic dielectric layer.

Example 18: an apparatus, comprising: a board; a package substrate coupled to the board, wherein the package substrate comprises: a glass core and an organic dielectric layer over the glass core; and wherein an edge profile of the package substrate comprise one or both of a protrusion or a recess; and a die coupled to the package substrate.

Example 19: the apparatus of Example 18, wherein the protrusion extends out from an edge of the glass core.

Example 20: the apparatus of Example 18 or Example 19, wherein the recess extends into the organic dielectric layer.

What is claimed is:

1. An apparatus, comprising:
a substrate with a first edge surface, wherein the substrate comprises a glass layer;
a via through a thickness of the substrate;
an organic dielectric layer over the substrate with a second edge surface; and
a recess into the second edge surface.

2. The apparatus of claim 1, further comprising:
a plurality of recesses into the second edge surface.

3. The apparatus of claim 2, wherein at least two of the plurality of recesses have depths from the second edge surface that are different from each other.

4. The apparatus of claim 1, wherein a protrusion extends out from the first edge surface.

5. The apparatus of claim 4, wherein the protrusion is at an approximate midpoint between a top surface of the substrate and a bottom surface of the substrate.

6. The apparatus of claim 4, wherein the first edge surface has a first surface roughness and a third edge surface of the protrusion has a second surface roughness that is greater than the first surface roughness.

7. The apparatus of claim 1, further comprising:
a bridge embedded within the organic dielectric layer, wherein the bridge electrically couples a first die over the organic dielectric layer to a second die over the organic dielectric layer.

8. The apparatus of claim 1, further comprising:
a dielectric layer over the first edge surface of the substrate.

9. The apparatus of claim 8, wherein the dielectric layer is over a top surface and a bottom surface of the substrate.

10. The apparatus of claim 1, wherein the substrate is electrically coupled to a board.

11. An apparatus, comprising:
a glass core, wherein the glass core has a protrusion extending out from a first edge surface of the glass core; and
an organic dielectric layer over the glass core, wherein the organic dielectric layer comprises a first recess and a second recess into a second edge surface of the organic dielectric layer.

12. The apparatus of claim 11, wherein the first recess has a first depth and the second recess has a second depth that is different than the first depth.

13. The apparatus of claim 12, wherein the first depth is up to approximately 25 μm.

14. The apparatus of claim 11, wherein the first edge surface has a first roughness and the protrusion has a third edge surface with a second roughness, and wherein the second roughness is greater than the first roughness.

15. The apparatus of claim 11, wherein the first edge surface is offset from the second edge surface.

16. The apparatus of claim 11, further comprising:
an electrically conductive via through the glass core.

17. The apparatus of claim 11, further comprising:
a bridge coupled to the organic dielectric layer, wherein the bridge electrically couples a first die over the organic dielectric layer to a second die over the organic dielectric layer.

18. An apparatus, comprising:
a board;
a package substrate coupled to the board, wherein the package substrate comprises:
a glass core and an organic dielectric layer over the glass core; and
wherein an edge profile of the package substrate comprise one or both of a protrusion or a recess; and
a die coupled to the package substrate.

19. The apparatus of claim 18, wherein the protrusion extends out from an edge of the glass core.

20. The apparatus of claim 18, wherein the recess extends into the organic dielectric layer.
